(19) United States
(12) Patent Application Publication
(10) Pub. No.: US 2025/0227860 A1
(43) Pub. Date: Jul. 10, 2025

(54) SEALS FOR POWER MODULES AND ELECTRIC ENERGY CONVERSION AND RELATED TRANSMISSION DEVICES

(71) Applicant: Eaton Intelligent Power Limited, Dublin 4 (IE)

(72) Inventors: Ping Zhang, Shenzhen (CN); Jian Wei, Shenzhen (CN); Huafeng Le, Shenzhen (CN); Yunmei Wu, Shenzhen (CN); Xiaolei Zhang, Shenzhen (CN)

(21) Appl. No.: 19/011,975

(22) Filed: Jan. 7, 2025

(30) Foreign Application Priority Data
Jan. 10, 2024 (CN) 202420068299.3

(51) Int. Cl. H05K 5/00

(52) U.S. Cl. CPC H05K 5/0091; H05K 5/0069; H05K 5/0073

(57) ABSTRACT

This disclosure relates to a seal for a power module and an electric energy conversion and transmission device. The seal for the power module comprising a housing having a first side surface and a second side surface opposite to each other and pins sticking out of the first side surface, the seal comprises a peripheral wall extending continuously in the circumferential direction to define a accommodating space, which is adaptable for accommodating the power module, the peripheral wall is elastic and has a first end and a second end opposite to each other, and the peripheral wall is configured such that when the power module is completely accommodated in the accommodating space, the first end of the peripheral wall is at least higher than the first side surface of the housing.

### CROSS-REFERENCE TO PRIORITY APPLICATION

This application claims priority to Chinese Patent Application No. 202420068299.3, filed Jan. 10, 2024, the content of which is hereby incorporated herein by reference in its entirety.

### TECHNICAL FIELD

This disclosure relates generally to the technical field of semiconductor switches and, in particular, to a seal for a power module and an electric energy conversion and transmission device.

### BACKGROUND

As a power semiconductor device, the insulated gate bipolar transistor (IGBT) is widely used in rail transit, smart grid, industrial energy conservation, electric vehicles, and new energy equipment due to its energy-saving, easy installation, easy maintenance, and stable heat dissipation. It has been found that some IGBT modules used in high temperature and high humidity environments may be affected by harmful components in the environment, which can easily lead to module failures. For example, a large amount of copper sulfide (CuS) accumulation and multiply dendrites appear in the IGBT module, some of which form bridges in the slots that should be insulated. Considering that the IGBT module is electrically connected to other electronic devices through pins during use, it becomes more difficult to seal and protect the IGBT module.

### SUMMARY

Some embodiments in the present disclosure aim to provide a seal for a power module that can at least solve some of the above technical problems.

Further embodiments in this disclosure aim to provide an electric energy conversion and transmission device using the above-improved seal.

According to some embodiments, a seal for a power module is provided, the power module comprises a housing having a first side surface and a second side surface opposite to each other and pins extending from the first side surface, the seal comprises a peripheral wall extending continuously in the circumferential direction to define an accommodating space, the accommodating space is adaptable for accommodating the power module, the peripheral wall is elastic and has a first end and a second end opposite to each other, and the peripheral wall is configured so that when the power module is completely accommodated in the accommodating space, the first end of the peripheral wall is at least higher than the first side surface of the housing.

The seal provided according to these embodiments is adaptable for power modules with pins, such as power semiconductor device IGBT modules, in which the power module is integrally contained in the seal from the top (first end) to the bottom (second end). After the power module is installed on the printed circuit board, the pins of the power module can contact the printed circuit board for electrical connection, and the elastic seal wraps around the power module. Since the top (first end) of the seal is higher than the top surface (first side surface) of the housing of the power module or higher than the top of the pins of the power module, after tightening the connectors (such as a screw) during installation, the top of the seal will be compressed to be roughly flush with the top surface of the housing of the power module, so that the top of the seal fits tightly to the printed circuit board. The seal of this solution can effectively isolate the power module from the surrounding environment, preventing harmful substances from the outside from invading and damaging the power module contained therein.

In some embodiments, the peripheral wall has an inner surface facing the accommodating space and an outer surface facing away from the accommodating space, wherein the distance between the outer surface and a mid-section of the seal extending between the first end and the second end gradually decreases along the direction from the second end to the first end.

In some embodiments, the outer surface includes a first surface segment close to the first end and a second surface segment close to the second end, wherein a slope of the first surface segment is smaller than a slope of the second surface segment.

In some embodiments, the peripheral wall has an inner surface facing the accommodating space and an outer surface facing away from the accommodating space, wherein a distance between the outer surface and a mid-section of the seal extending between the first end and the second end is constant along a direction from the second end to the first end.

In some embodiments, a rib extending between a first end and a second end is formed on an inner surface of the peripheral wall facing the accommodating space.

In some embodiments, the peripheral wall is configured such that when the power module is completely accommodated in the accommodating space, the first end of the peripheral wall is 1-2 mm higher than the first side surface of the housing.

In some embodiments, the peripheral wall is configured such that when the power module is completely accommodated in the accommodating space, the second end of the peripheral wall is flush with the second side surface of the housing.

In some embodiments, the seal is configured as an insulating seal.

In some embodiments, the power module is an insulated gate bipolar transistor.

According to still further embodiments, an electric energy conversion and transmission device comprising a printed circuit board assembly, a power module with pins, and a heatsink assembled together is provided, wherein the power module is located between the printed circuit board assembly and the heatsink, and the pins of the power module are electrically connected to the printed circuit board assembly, and the electric energy conversion and transmission device also includes the aforementioned seal, wherein the power module is completely accommodated in the seal, and the seal is pressed between the printed circuit board assembly and the heatsink.

Some of the other features and advantages of this disclosure will be apparent to those skilled in the art after reading this application, and the other parts will be described in the following specific embodiments in conjunction with the accompanying drawings.

### BRIEF DESCRIPTION OF THE DRAWINGS

The embodiments of this disclosure are described in detail below with reference to the accompanying drawings, wherein:

FIG. 1 is a partial view of an electric energy conversion and transmission device according to some embodiments of this disclosure, showing the assembled PCBA, IGBT module and heatsink.

FIG. 2 is a schematic diagram of a seal according to some embodiments of this disclosure.

FIGS. 3A-3C are plan views of the seal of FIG. 2.

FIG. 3D is an enlarged view of FIG. 3C at A.

FIG. 4 is a schematic diagram of a seal according to some embodiments of this disclosure.

FIGS. 5A-5C are plan views of the seal of FIG. 4.

FIG. 5D is an enlarged view of FIG. 5C at B.

FIG. 6 is a schematic diagram of a seal according to some embodiments of this disclosure.

### DETAILED DESCRIPTION

Now, with reference to the accompanying drawings, the schematic schemes of the seal for power modules and the power conversion and transmission devices disclosed herein are described in detail. Although the drawings are provided to present some embodiments of this disclosure, the drawings do not have to be drawn according to the dimensions of the specific embodiments, and certain features may be enlarged, removed or partially cut to better illustrate and explain the disclosure of this disclosure. Some components in the drawings can be adjusted in position according to actual needs without affecting the technical effect. The phrase “in the drawings” or similar terms appearing in the specification do not necessarily refer to all drawings or examples.

Certain directional terms used to describe the drawings below, such as “inside”, “outside”, “above”, “below” and other directional terms, will be understood to have their normal meanings and refer to those directions involved when viewing the drawings normally. Unless otherwise specified, the directional terms described in this specification are basically in accordance with the conventional directions understood by those skilled in the art.

The terms “first”, “first one”, “second”, “second one” and the like as used herein do not indicate any order, quantity or importance, but are used to distinguish one component from other components.

The terms “elastomer” or “elasticity” as used herein generally refer to a material that is deformed in at least one direction (e.g., longitudinally or transversely or longitudinally and transversely) by applying an external force (tension or pressure), such as being stretched in response to tension or being compressed in response to pressure, and that can be restored to approximately its original size or configuration by removing the external force.

As one of the core components of power conversion and transmission devices, power modules with pins are widely used in the field of smart devices or new energy devices. Power modules can be, for example, IGBT modules or SiC modules. Power conversion and transmission devices can be, for example, uninterruptible power modules (UPM) or uninterruptible power supplies (UPS), which are used in applications such as charging piles and motor drives for electric vehicles. The pins of power modules are used to contact other electronic devices, such as printed circuit board assembly (PCBA), to electrically access the circuit. Therefore, one of the problems that this description aims to solve lies in protecting the power modules without hindering their normal connection to reduce the likelihood that the surrounding environment invades and corrodes the power modules.

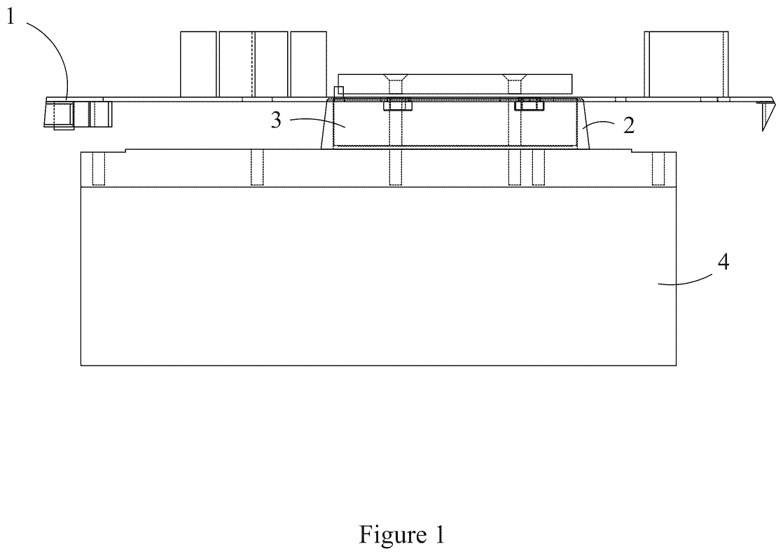

FIG. 1 shows an embodiment of an electric energy conversion and transmission device, wherein a part of the device including PCBA 1, power module 3 and heatsink 4 is shown. Here, PCBA 1, power module 3 and heatsink 4 are assembled together detachably through connectors, such as screws, and the pins of power module 3 contact the copper surface of PCBA 1 to carry current. As a protective structure for power module 3, seal 2 is arranged between PCBA 1 and heatsink 4 and wraps power module 3. With the application of connectors, elastic seal 2 is clamped by PCBA 1 and heatsink 4 from both sides, so that it can be tightly attached to PCBA 1 at the first end and tightly attached to heatsink 4 at the second end.

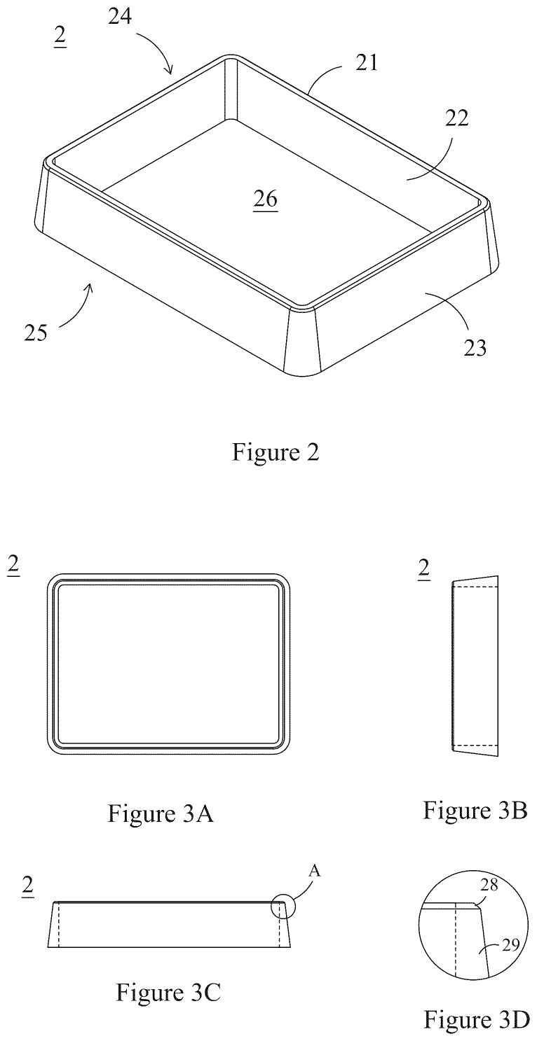

FIG. 2 and FIG. 3A-3C illustrate embodiments of the seal 2. As shown in the figure, the elastic peripheral wall 21 of the seal 2 extends continuously to form a circumferentially closed square frame configuration, which has a first end 24 (or referred to as the “top end”) and a second end 25 (or referred to as the “bottom end”) opposite to each other. The internal accommodating space 26 defined by the peripheral wall 21 is hollow and open in the direction from the first end 24 to the second end 25, and is used to accommodate the power module 3. The contour of the inner surface 22 of the peripheral wall 21 can be confronted with the power module 3 to be installed. For example, the power module 3 has a housing configured as a rectangular block, the housing having a first side surface (or referred to as the “top surface”) and a second side surface (or referred to as the “bottom surface”) opposite to each other, and the pins extend from the first side surface of the housing, and the extended end of the pins is also called the top end of the pins. In this regard, the inner surface 22 of the peripheral wall 21 also constructs as a rectangular contour, and for the mid-section of the seal 2 extending between the first end 24 and the second end 25, the distance from anywhere of the inner surface 22 to the mid-section is substantially constant. The accommodating space 26 is open at both the first end 24 and the second end 25 of the peripheral wall 21, so as to be hollow from top to bottom. In this way, the seal 2 surrounds the power module 3 in the circumferential direction, but has no effect on the first side and the second side of the power module 3. The size between the first end 24 and the second end 25 of the peripheral wall 21 is designed so that when the power module 3 is completely accommodated in the accommodating space 26, the first end 24 of the peripheral wall 21 is at least a certain distance higher than the first side of the housing of the power module 3, such as 1-2 mm higher. In this description, “completely accommodated in the accommodating space” means that when no external force is applied to the seal 2, the peripheral wall 21 can at least cover the portion of the housing of the power module 3 from the first side to the second side.

In some embodiments, the second side surface of the housing of the power module 3 is flush with the end surface of the second end 25 of the peripheral wall 21 of the seal 2, while the first end 24 of the peripheral wall 21 of the seal 2 is 1-2 mm higher than the first side surface of the housing of the power module 3.

In further embodiments, the second side surface of the housing of the power module 3 is flush with the end surface of the second end 25 of the peripheral wall 21 of the seal 2, while the first end 24 of the peripheral wall 21 of the seal 2 is 1-2 mm higher than the top of the pins of the power module 3.

By designing the peripheral wall 21 of the seal 2 to be higher than the top surface of the power module 3 by a certain distance, when the seal 2 and the power module 3 are installed between the PCBA 1 and the heatsink 4, after tightening the connectors, the seal 2 will be pressed between the PCBA 1 and the heatsink 4, with the first end 24 abutting against the PCBA 1 and the second end 25 abutting against the heatsink 4. In this way, the seal 2 can be closely attached to the surface of the PCBA 1 and the surface of the heatsink 4, preventing harmful components in the external environment from invading the power module 3 and causing damage thereto.

The seal 2 is made of an insulating material with a certain elasticity, such as silicone or rubber. The Shore A hardness can be between 30-50, for example, 40. This hardness can make the seal 2 have enough elasticity to cope with sealing and compression without affecting the electrical connection between the PCBA 1 and the power module 3.

In embodiments shown in FIG. 2 and FIG. 3A-3C, the seal 2 is configured to be similar to a tower. Specifically, the outer surface 23 of the seal 3 gradually tilts toward the mid-section of the seal 2 along the direction from the second end 25 to the first end 24, so that the distance between the outer surface 23 and the mid-section gradually decreases along the direction from the second end 25 to the first end 24. This tilt of the outer surface 23 helps to reduce the convex deformation of the seals after being compressed, and also enables the seal to tightly wrap the power module to achieve a good sealing effect.

In some embodiments, the tilted outer surface 23 may have a uniform slope in the direction from the second end 25 to the first end 24. In further embodiments, the outer surface 23 may be divided into surface segments having different slopes. As shown in FIG. 3D, the first surface segment 28 of the outer surface 23 near the first end 24 has a first slope, and the second surface segment 29 near the second end 25 has a second slope, wherein the first slope is smaller than the second slope. The slope calculation formula here is Y/X, where Y is the vertical distance change of the surface segment, and X is the horizontal distance change of the surface segment. Here, the dimension of the first surface segment 28 is significantly smaller than that of the second surface segment 29.

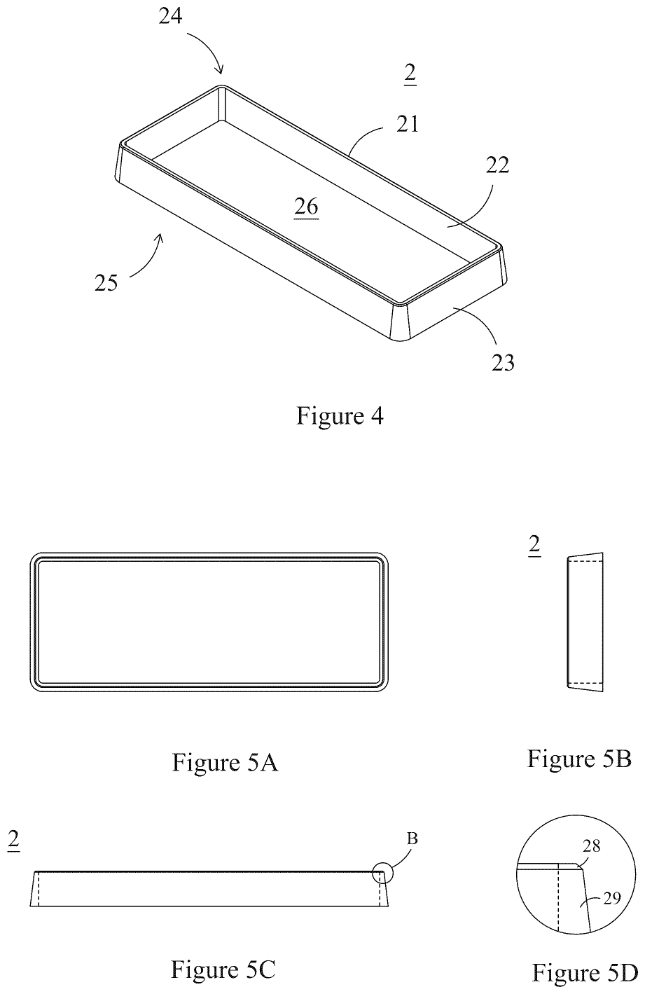

FIG. 4 and FIG. 5A-5C show embodiments of the seal 2. The difference between these embodiment and the embodiments discussed above is that the frame enclosed by the peripheral wall 21 of the seal 2 in the these embodiments is more “narrow and long” than the frame enclosed by the peripheral wall 21 of the seal 2 in the embodiments discussed above. In embodiments illustrated in FIG. 4 and FIG. 5A-5C, the outer surface 23 of the peripheral wall 21 can also be configured as an tilted surface gradually tilted toward the mid-section of the seal 2 along the direction from the second end 25 to the first end 24, wherein as shown in FIG. 5D, the slope of the first surface segment 28 close to the first end 24 is less than the slope of the second surface segment 29 close to the second end 25.

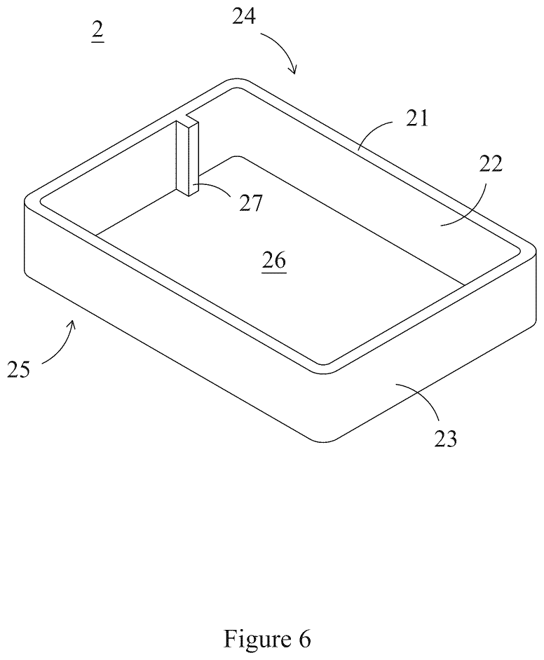

FIG. 6 shows further embodiments of the seal 2. As shown in the figures, the elastic peripheral wall 21 of the seal 2 extends continuously to form a closed frame configuration. The frame configuration has a first end 24 and a second end 25 that are opposite to each other. The internal accommodating space 26 defined by the peripheral wall 21 is used to accommodate the power module 3. The contour of the inner surface 22 of the peripheral wall 21 can be adapted to the power module 3 to be installed. For example, the power module 3 has a housing configured as a rectangular block, and the pins extend from the first side of the housing. In this regard, the inner surface 22 of the peripheral wall 21 also surrounds a rectangular contour, and for the mid-section extending between the first end 24 and the second end 25 of the seal 2, the distance from the inner surface 22 to the mid-section is substantially constant.

Different from the previous embodiments, the inner surface 22 of the seal 2 is configured with a rib 27. The rib 27 extends between the first end 24 and the second end 25, and can enhance the structural strength.

The accommodating space 26 is open at both the first end 24 and the second end 25 of the peripheral wall 21, so as to be through from top to bottom. In this way, the seal 2 surrounds the power module 3 in the circumferential direction, but has no effect on the first side surface and the second side surface of the power module 3. Similar to the previous embodiments, the dimension between the first end 24 and the second end 25 of the peripheral wall 21 is also designed so that when the power module 3 is completely accommodated in the accommodating space 26, the peripheral wall 21 is at least a certain distance higher than the first side surface of the housing of the power module 3 at the first end 24, such as 1-2 mm higher. In particular, when the power module 3 is completely accommodated in the accommodating space 26, and when the second side surface of the power module 3 is flush with the end surface of the second end 25 of the peripheral wall 21, the first end 24 of the peripheral wall 21 is 1-2 mm higher than the first side surface of the power module 3, or 1-2 mm higher than the top of the pins of the power module 3.

In embodiments shown in FIG. 6, the outer surface 23 of the seal 3 is configured as a plane extending substantially vertically, i.e., along the direction from the second end 25 to the first end 24, the distance between the outer surface 23 and the mid-section of the seal 2 remains constant.

Installation verification of the assembly of the seal 2 with the power module 3 provided herein includes using pressure paper to check whether the power connection is good and using a feeler gauge to check the gap between the seal 2 and the PCBA. The results were all qualified.

According to the torque test results on the test paper, one is the bolt torque of 2 N·m, another is the bolt torque of 2.5 N·m, and the third is the bolt torque of 2.3 N·m. The results show that the color change of the test paper of 2.3/2.5 N·m was better than that of 2 N·m. An example torque range of IGBT is 2.0 N·m-2.5 N·m.

Feeler gauge detection shows that within the preferred torque range, a 0.02 mm feeler gauge cannot be inserted between the IGBT and the PCBA, indicating that the seal provided in this article can effectively isolate the contained power module from the surrounding environment without affecting the electrical connection.

The HV-H2S test was performed on the assembly of the seal 2 and the power module 3 provided in this description.

Two sets of PCBA and IGBT module assemblies were prepared, wherein in one set of PCBA and IGBT module assemblies, the IGBT module was accommodated in the seal as described above, and in the other set of PCBA and IGBT module assemblies, the IGBT module was in a bare state without any seal for protection.

The two sets of PCBA and IGBT module components were simultaneously fed into the HV-H2S tester.

The test parameters were set as follows: temperature 60° C., humidity 93% RH, H2S 25 ppm, NO2 4 ppm, CL2 0.4 ppm, SO2 1 ppm, and test time 338 hours (h).

The IGBT modules in the two sets of PCBA and IGBT module assemblies that have undergone testing were opened.

By observing the internal structures of the two IGBT modules under a microscope, it was found that there were obvious differences between the IGBT module protected by seal and the IGNT module without seal.

The status of the IGBT module and PCBA protected by seal after testing was detected. The status of the IGBT module and PCBA not protected by seal after testing was also detected.

Obviously, only a small amount of shrapnel in the IGBT module protected by the seal changed color. There were no corrosion marks or dendrites in the DBC area and the area where the DBC contacts the shrapnel. No corrosion problems were found in all the insulating grooves, and there was no sign of dendrite growth. The chip surface was intact with no signs of corrosion.

On the contrary, in the IGBT modules without seal protection, most of the shrapnel underwent corrosion discoloration, there were obvious corrosion marks at the contact between the shrapnel and DBC, dendrites were seen everywhere in the insulation groove, and there were no corrosion marks on the chip surface.

From this, it can be concluded that after the IGBT module is installed with a seal, it can be effectively isolated from the surrounding air, avoiding chemical reactions in the internal structure caused by the invasion of external harmful substances, thereby preventing the IGBT module from failure.

It should be understood that although this description is described according to various embodiments, not every embodiment contains only one independent technical solution. This narrative method of the description is only for the sake of clarity. Those skilled in the art should regard the description as a whole. The technical solutions in each embodiment may also be appropriately combined to form other implementation methods that can be understood by those skilled in the art.

The above description is only illustrative embodiments of this disclosure and is not intended to limit the scope of this disclosure. Any equivalent changes, modifications and combinations made by any technician in the field without departing from the concept and principle of this disclosure shall fall within the scope of protection of this disclosure.

What is claimed is:

1. A seal for a power module comprising:
a housing having a first side surface and a second side surface opposite to each other; and
pins extending out of the first side surface,
wherein the seal comprises a peripheral wall extending continuously in a circumferential direction to define an accommodating space, that is adaptable for receiving the power module, the peripheral wall being elastic and having a first end and a second end opposite to each other, and the peripheral wall being configured such that when the power module is completely accommodated in the accommodating space, the first end of the peripheral wall is at least higher than the first side surface of the housing.

2. The seal of claim 1, wherein the peripheral wall has an inner surface facing the accommodating space and an outer surface facing away from the accommodating space, wherein a distance between the outer surface and a mid-section of the seal extending between the first end and the second end gradually decreases in a direction from the second end to the first end.

3. The seal of claim 2, wherein the outer surface comprises a first surface segment close to the first end and a second surface segment close to the second end, wherein a slope of the first surface segment is smaller than a slope of the second surface segment.

4. The seal of claim 1, wherein the peripheral wall has an inner surface facing the accommodating space and an outer surface facing away from the accommodating space, wherein a distance between the outer surface and a mid-section of the seal extending between the first end and the second end is constant in a direction from the second end to the first end.

5. The seal of claim 1, wherein a rib extending between the first end and the second end is formed on an inner surface of the peripheral wall facing the accommodating space.

6. The seal of claim 1, wherein the peripheral wall is configured such that when the power module is completely accommodated in the accommodating space, the first end of the peripheral wall is 1 to 2 mm higher than the first side surface of the housing.

7. The seal of claim 1, wherein the peripheral wall is configured such that when the power module is completely accommodated in the accommodating space, the second end of the peripheral wall is flush with the second side surface of the housing.

8. The seal of claim 1, wherein the seal is configured as an insulating seal.

9. The seal of claim 1, wherein the power module is an insulated gate bipolar transistor.

10. An electric energy conversion and transmission device comprising:
a printed circuit board assembly, a power module with pins, and a heatsink assembled together,
wherein the power module is located between the printed circuit board assembly and the heatsink, and the pins of the power module are electrically connected to the printed circuit board assembly;
wherein the electric energy conversion and transmission device further comprises a seal according to claim 1; and
wherein the power module is completely accommodated in the seal, and the seal is pressed between the printed circuit board assembly and the heatsink.
